(19) United States
(12) Patent Application Publication
(10) Pub. No.: US 2021/0185424 A1
(43) Pub. Date: Jun. 17, 2021

(54) MOUSE WITH EARBUD STORAGE AND CHARGING

(71) Applicant: Hewlett-Packard Development Company, L.P., Spring, TX (US)

(72) Inventors: Chris Kowalk, Fort Collins, CO (US); Melytza Pluchino, Spring, TX (US); Ligy Kurian, Spring, TX (US)

(73) Assignee: Hewlett-Packard Development Company, L.P., Spring, TX (US)

(21) Appl. No.: 17/042,146

(22) PCT Filed: Sep. 4, 2018
(86) PCT No.: PCT/US2018/049344

§ 371 Date: Sep. 27, 2020

(51) Int. Cl. H04R 1/10; G06F 3/0354; H02J 50/00; H02J 50/20; H02J 7/00

(52) U.S. Cl. CPC H04R 1/1025; G06F 3/03543; H02J 50/005; H04R 2225/31; H02J 7/0049; H02J 2310/22; H02J 2207/30; H02J 50/20

(57) ABSTRACT

A mouse for use with a computer system, the mouse including: a body, the body containing a chamber, the chamber to hold an earbud; a receiver to receive power from a source external to the mouse; and a controller, to allocate power received from the external source between charging a battery in the mouse and charging a battery in the earbud.

### BACKGROUND

Peripherals for electronic devices continue to increase in number and usage. Many peripherals use power to operate. The power may be provided by a direct wired connection. The power may be provided wirelessly. The power may be provided from a battery and/or other storage.

### BRIEF DESCRIPTION OF THE DRAWINGS

The accompanying drawings illustrate various examples of the principles described herein and are a part of the specification. The illustrated examples do not limit the scope of the claims.

FIG. 1 shows an example of a mouse consistent with this specification.

FIG. 2 shows an example of a mouse consistent with this specification.

FIG. 3 shows a side view of a mouse in an example consistent with this specification.

FIG. 4 shows an example of a mouse consistent with this specification.

FIG. 5 shows a flowchart of a method of changing earbuds and a mouse consistent this specification.

Throughout the drawings, identical reference numbers designate similar, but not necessarily identical, elements. The figures are not necessarily to scale, and the size of some parts may be exaggerated or minimized to more clearly illustrate the example shown. The drawings provide examples and/or implementations consistent with the description. However, the description is not limited to the examples and/or implementations shown in the drawings.

### DETAILED DESCRIPTION

One peripheral commonly used with electronic devices is the mouse. The mouse is a unit that capable of providing x and y motion as well as well as a button actuation to an electronic device. While the name mouse is inspired partially by the resemblance of a cable connecting the mouse to the electronic device to a mouse's tail, wireless mice are also used, including with portable devices such as laptop computers.

Another peripheral used with electronic devices are earbuds. Earbuds are earphones that fit partially into the ear. They are small compared with headsets and similar audio output devices. Earbuds may be wirelessly recharged, have an internal battery, and are wirelessly connected to receive data (music) from another device. The small size of earbuds limits the battery size and the session length before the earbuds need to be recharged, with session lengths of 4 to 8 hours being common. Further, the small size of the earbuds makes them vulnerable to being lost and/or misplaced.

Among other examples, this specification describes a mouse for use with a computer system. The mouse includes: a body, the body containing a chamber, the chamber to hold an earbud; a receiver to receive power from a source external to the mouse; and a controller, to allocate power received from the external source between charging a battery in the mouse and charging a battery in the earbud.

Among other examples, this specification also describes a mouse for use with a computer system, the mouse including: a body, the body containing a chamber, the chamber to hold a pair of earbuds; a receiver to receive power from a source external to the mouse; and a controller to allocate power received from the external source between charging a battery in the mouse and charging a battery in the earbud based on detected levels of charge in the battery in the mouse and the battery in the earbud.

This specification also describes a method of charging earbuds, the method including: determining, with a controller, if the mouse is coupled to an external power source; if the mouse is coupled to an external power source, the controller distributing power from the external power source between a pair of earbuds in the mouse and the mouse; and if the mouse is not coupled to an external power source, charging by the controller, the earbuds in the mouse from a battery in the mouse.

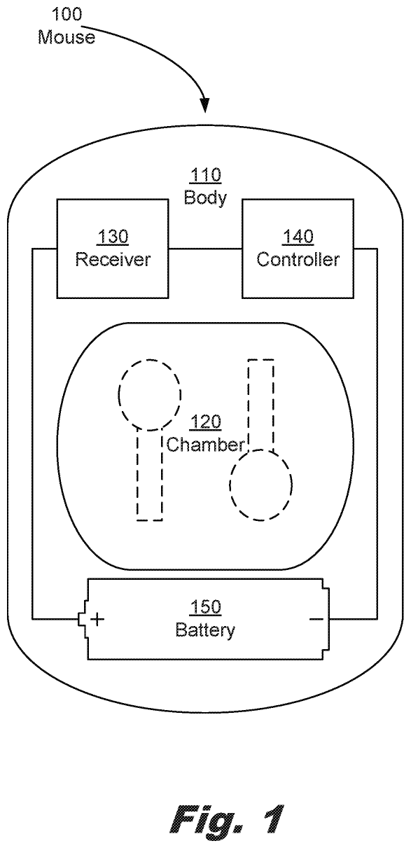

Turning now to the figures, FIG. 1 shows an example of a mouse (100) consistent with this specification. The mouse (100) includes: a body (110), the body (110) containing a chamber (120), the chamber (120) to hold an earbud; a receiver (130) to receive power from a source external to the mouse (100); and a controller (140), to allocate power received from the external source between charging a battery (150) in the mouse (100) and charging a battery (150) in the earbud.

The mouse (100) may be a wireless mouse (100). The mouse (100) may be a wired mouse (100). The mouse (100) may include a button to provide a signal to an electronic device. The mouse (100) may include multiple buttons. The mouse (100) may include a scroll wheel.

The body (110) of the mouse (100) may be shaped to conform to a hand.

The chamber (120) in the body (110) may be shaped hold an earbud. The chamber in the body (110) may be shaped to hold a pair of earbuds. In an example, the chamber (120) is not accessible through a surface of the body (100) contacted by the hand during typical use of the mouse (100). This may avoid a seam and/or similar feature that could make using the mouse (100) unpleasant.

The chamber (120) may be accessible through a bottom surface of the mouse. The bottom surface is opposite the surface contacted by the hand during typical use. The bottom surface is the surface of the mouse (100) which rests on a surface during use. In older style mice (100), the bottom surface included a mechanical ball that rolled with motion of the mouse (100) and served as a motion sensor. Current mice (100) often use an LED and an optical sensor to as a motion sensor. The motion sensor to detect mouse motion may be located near a center of the bottom surface of the mouse (100). This motion sensor may be positioned towards an edge of the bottom surface to provide a larger area for the chamber (120). In an example, the motion sensor may be position towards the “front” of the mouse (100). The front of the mouse being defined as the edge near the fingers of the hand holding and operating the mouse. The buttons of the mouse (100) are generally located near the front of the mouse on the top surface. Getting all these systems into a shared space would be a tight for an older, ball-type mouse (100), however, the use of the LED and optical sensor allows the motions sensor to be placed in a smaller area and readily accommodated in the front portion of the mouse (100) body (110).

In an example, the chamber (120) is sized to hold a pair of earbuds and the controller (140) allocates power received from the external source between charging the battery (150) in the mouse (100) and charging batteries (150) in the earbuds.

In an example, the chamber (120) includes a cover panel. The panel serves to cover the chamber (120). This may reduce dirt and/or other material from getting into the chamber. The panel may form part of the bottom surface of the body (110) of the mouse (100). The panel may be removable. The panel may be hinged. the panel may include a latch and/or release.

In an example, the chamber (120) includes a magnet to align the earbud and facilitate charging. The magnet may also help hold the earbud in place. The magnet may also help hold the panel in place, for example by including a magnet and/or magnetizable material on and/or as part of the panel.

The chamber (120) may be accessible through a side of the mouse (100). In an example, a release causes a tray to slide out from the chamber (120). The earbuds may be placed into the tray and the tray slide back into the chamber (120). This approach may be useful in a wireless antenna is located in the bottom surface of the body (110).

In an example, a portion of the top surface of the body (110) of the mouse (100) is removable. The portion may be designed to open instead of being removed. the opening could then be used to access the chamber (120), for example, to place and/or remove earbuds. The portion may slide off, for example by moving towards a back edge opposite the front of the body of the (110) mouse (100). As with the side access above, this approach may provide a benefit when the bottom of the body (110) of the mouse (100) includes an antenna.

The chamber (120) may be used without a panel. This makes access to the earbuds quicker but also increases the potential for one to fall out and be lost.

The receiver (130) receives power from a source external to the mouse. The receiver (130) may be a port. In an example, the receiver (140) is a universal serial bus (USB) compatible connection. The receiver (130) may be an outlet. The receiver (130) may be an inductive coil. The receiver (130) may receive power that has been transmitted wirelessly.

The receiver (130) provides power to charge a battery on the mouse (110). The receiver (130) provides power to charge a battery on an earbud in the chamber (120). The receiver (130) may provide power for current operation of the mouse (100). The receiver (130) may provide power for the current operation of the mouse (100) through the battery (150) of the mouse (100).

The power provided to charge the battery (150) of the earbud may be provided wirelessly and/or via a wired connection. In one example, a micro USB plug is provided to charge the earbud in the chamber (120). A variety of inductive and/or resonant charging approaches may be used to provide power to the receiver (130). In an example, the charging is consistent with the Qi standard. However, other charging approaches, e.g., Power Maters Alliance (PMA) are also consistent with this disclosure.

The controller (140) allocates power between the battery (150) for the mouse (100) and power (150) used to charge the battery(s) of the earbud(s). The controller (150) allocates the power received at the receiver (140). The controller (150) may transfer power from the battery (150) the mouse (100) to a battery of the earbud.

The mouse (100) includes a battery (150). The battery in the mouse may be removable. The battery (150) in the mouse (100) may be integrated with the mouse (100) so as to be not removable without a tool. The earbud also contains a battery (150). The battery (150) in the ear bud is rechargeable when in the chamber (120). The controller (140) allocated power between the battery (150) of the mouse (100) and the battery(s) (150) of the earbud(s).

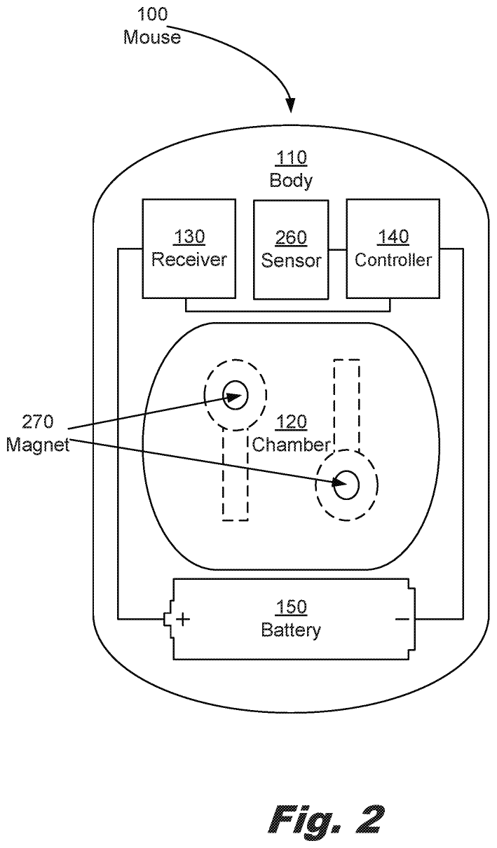

FIG. 2 shows an example of a mouse (100) consistent with this specification. The mouse (100) includes: a body (110), the body (110) containing a chamber (120), the chamber (120) to hold an earbud; a receiver (130) to receive power from a source external to the mouse (100); and a controller (140), to allocate power received from the external source between charging a battery (150) in the mouse (100) and charging a battery (150) in the earbud. FIG. 2 also shows a sensor (260) associated with the controller (140) and magnets (270) in the chamber (120).

The sensor (260) may be used to measure a charge level of the battery (150) in the mouse (100). The sensor (260) may be used to measure a charge level of a battery (150) in an earbud in the chamber (120). A single sensor (260) may be used for both of these operations. Multiple sensors (260) may be used. The sensor (260) provides the measurement of charge to the controller (140). The measured charge is used to determine the allocation of power between the batteries (150). The controller (140) receives a measured charge level of the battery (150) in the mouse (100) and a measured charge level of the battery (150) in the earbud and wherein the controller (140) uses the measured charge levels of the batteries (150) to determine the allocation of power received from the external source.

For example, if the receiver (130) is receiving power from an external source, and the battery (150) in the mouse (100) is greater than a first threshold, e.g., 90% of maximum charge, the controller (140) may direct all charging to the battery(s) (150) in the earbud(s) in the chamber (120). If the battery (150) in the mouse (100) is below a second threshold, e.g. 20% of maximum charge, the controller (140) may direct all charging to the battery (150) in the mouse (100) until the charge in the battery (150) in the mouse (100) reaches the second threshold. When the value of the battery (150) in the mouse (100) is between the second and first thresholds, the controller (140) may allocate power between the battery (150) in the mouse (100) and the battery(s) (150) in the earbud(s) in the chamber (120). For example, the controller (140) may allocate power to the mouse (100) to keep the battery (150) charge constant and apply the remaining power to charge the battery(s) (150) in the earbud(s). The controller (140) may adopt an earbuds first charging strategy until the power level drops the second threshold. The controller (140) may distribute power between the batteries based on charge levels and/or user priorities.

In an example, the controller (140) receives a signal from a processor to prioritize charging the battery (140) in the mouse and/or the earbud. This signal may be provided by an app, for example, on a phone and/or a laptop. In an example, the app also provides notification of charging status and/or reaching a charge level in a battery (150) being charged.

The mouse (100) may include a magnet (270) to retain the earbud in the chamber (120). The magnet (270) may increase the efficiency of power transfer to the earbud. The magnet (270) may help align and/or orient the earbud in the chamber (120). The chamber (120) may include contouring and/or supports to orient and/or retain the earbud(s). The magnet (270) may be selected to provide enough attraction to hold the earbuds in the chamber (120) when held upside down but to release them when tapped and/or shaken.

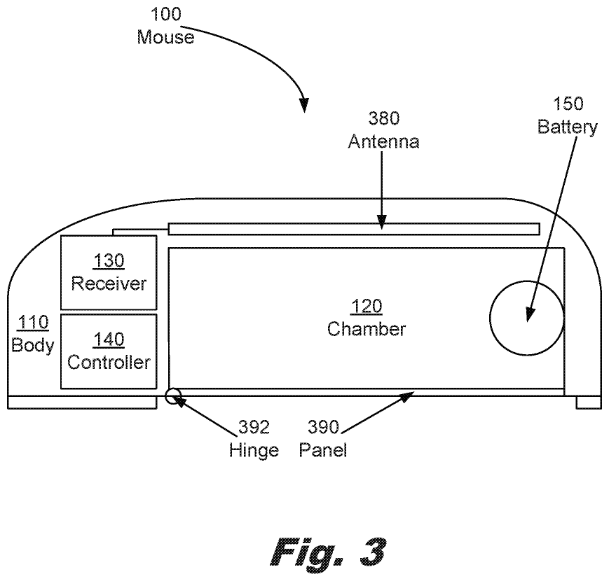

FIG. 3 shows a side view of a mouse (100) in an example consistent with this specification. The mouse (100) is a mouse (100) for use with a computer system. The mouse includes: a body (110), the body (110) containing a chamber (120), the chamber (120) to hold a pair of earbuds; a receiver (130) to receive power from a source external to the mouse (100); and a controller (140) to allocate power received from the external source between charging a battery (150) in the mouse and charging a battery (150) in the earbud based on detected levels of charge in the battery (150) in the mouse (100) and the battery (150) in the earbud. This example includes an antenna (380). FIG. 3 also shows a panel (390) for covering and accessing the chamber (120). The implementation in FIG. 3 has a hinge (392) to allow the panel (390) to move while remaining attached to the mouse (100).

The antenna (380) may be used for wirelessly charging the battery (150) in the mouse (100). The antenna (380) may be used for wirelessly charging the battery (150) in an earbud in the chamber (120). In an example, the energy is first received by the antenna and stored in a battery (150) on the mouse (100). The energy is then transmitted from the antenna (380) to charge the battery (150) in the earbud. Two antennas (380) may be used, for example a large antenna to charge the mouse and a smaller antenna (380) located near the chamber to transfer power to the earbud. A magnet (270) may be used to increase the efficiency of the transfer and/or to align the antenna (380) with the earbud in the chamber (120).

The chamber may include a second antenna (380) oriented at 90 degrees to the first antenna (380) the ear buds may be placed so as to be parallel to the second antenna (380). The earbuds may be placed on either side of the second antenna (380) to provide proximity and reduces losses between the second antenna (380) and the earbuds. The transfer to the first antenna (380) and from the second antenna (380) to the earbuds may be performed at different frequencies.

The panel (390) opens to allow access to the chamber (120). In an example the panel (120) remains attached when open. The attachment may be a hinge (392) as shown. The attachment may be a tether. The attachment may reduce instances of dropping and/or losing the panel (390). The panel (390) may also reduce dust, dirt, and/or other contamination getting into the chamber (120).

As shown in FIG. 3, the panel (390) may be located on a bottom surface of the body (110) of the mouse (100). The panel (390) may be on a side surface of the body of the mouse (100). The panel (390) may be on a top surface of the mouse (100). In an example, the top surface of the mouse slides backward to provide access to the chamber (120). This approach may favor placing the antenna (380) between the chamber (120) and the bottom surface of the mouse (100). This may provide more effective wireless energy transfer from a surface the mouse (100) is resting on by reducing the separation between a transmitting antenna and the antenna in the mouse (380).

The battery (150) may be accessible in the chamber (120). This may allow a single panel to provide access for both battery operations and the placing the earbud(s) for charging. The controller (140) may be visible from the chamber (120). In an example, a signal controlled by the controller (140) is visible in the chamber (120). The signal could be, for example, a light emitting diode (LED) to provide a visual notification and/or a speaker to provide an audio notification. The notification could be provided when the charge level in the battery (150) of the earbud reaches a predetermined threshold, e.g., 80% charged. A notification could also be provided when the battery (150) of the mouse reaches a predetermined threshold, e.g., 20% charge remaining.

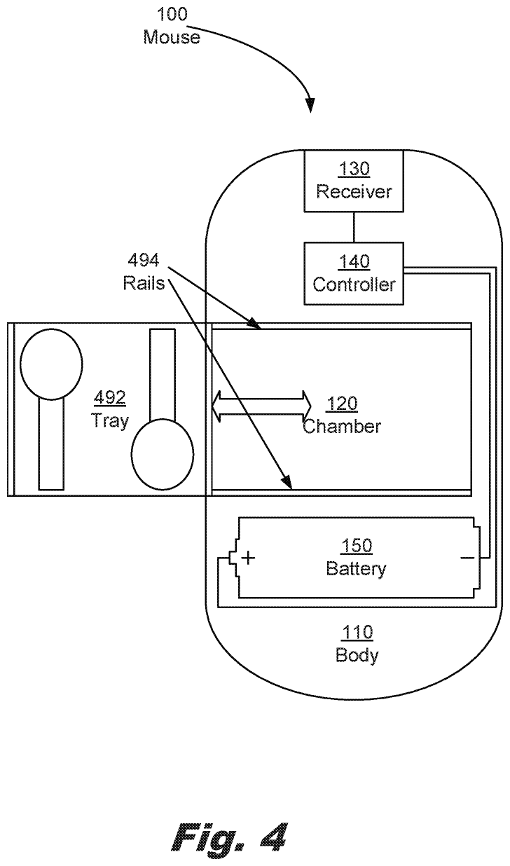

FIG. 4 shows an example of a mouse (100) consistent with this specification. The mouse (100) includes a body (100) with a chamber (120), a receiver (130) to receive power from an external source, and a controller (140) to allocate received power between the battery (150) of the mouse and the battery (150) of an earbud being charged. This example also includes a tray (492) which may slide out from the chamber on rails (494).

The tray (492) contains impressions to received and hold the earbuds while charging and/or for storage. The tray (492) may be pushed by a spring and/or other mechanism to extend from the chamber (120). In an example, a latch releases the tray (492) to extend and when the tray (492) is pushed back into the chamber (120) the spring is compressed and the latch reset. The chamber (120) may include rails (494) and/or other guiding and/or aligning features to provide a smooth deployment and reloading of the tray (492).

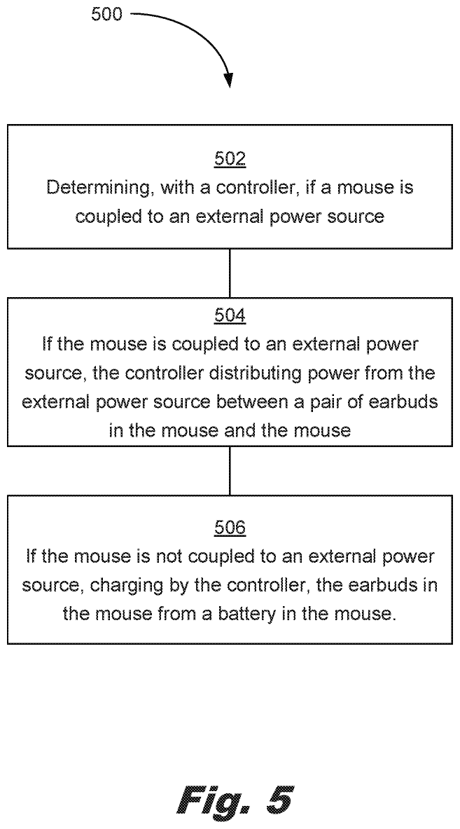

FIG. 5 shows a flowchart of a method (500) of changing earbuds and a mouse consistent this specification. The method (500) includes: determining, with a controller (140), if a mouse (100) is coupled to an external power source (502); if the mouse (100) is coupled to an external power source, the controller (140) distributing power from the external power source between a pair of earbuds in the mouse (100) and the mouse (100) (504); and if the mouse (100) is not coupled to an external power source, charging by the controller (140), the earbuds in the mouse (100) from a battery (150) in the mouse (100) (506).

The method (500) includes determining, with a controller (140), if a mouse (100) is coupled to an external power source (502). In an example, this includes querying a receiver (140) designed to receive power from an external power source. The receiver (140) may include an antenna (380) and receive power wirelessly. In another example, the controller (140) may measure a charge level of a battery (150) in the mouse (100). The controller (140) may repeat this measurement and if the charge level is increasing, the controller may conclude that the battery is being charged by an external power source. The controller (140) may use a sensor to measure the charge level of the battery (150).

The method (500) includes if the mouse (100) is coupled to an external power source, the controller (140) distributing power from the external power source between a pair of earbuds in the mouse (100) and the mouse (100) (504). The controller (140) controls distribution of charge between the mouse (100) and the earbuds. The controller (140) may receive charge levels from the battery (150) in the mouse (100) and the battery (150) in an earbud. The controller (140) may use those charge levels to determine how to allocate the power received from the external power source. In an example, the earbuds are charged wirelessly.

The method (500) includes if the mouse (100) is not coupled to an external power source, charging by the controller (140), the earbuds in the mouse (100) from a battery (150) in the mouse (100) (506). If the mouse (100) is not receiving power and the user has put the earbuds into the chamber (120), the controller (140) may presume the user desires to charge the earbuds using the battery (150) of the mouse (100). In an example, controller (140) may check the charge level in the battery (150) of the mouse (100) and not charge the earbuds in the charge level is below a threshold, for example, below 20% of the maximum battery (150) charge.

The method (500) may further include providing a notification when the earbuds reach a predetermined charge level. The notification may be provided by an indicator on the mouse (100). The indicator may be a speaker. The indicator may be an LED. The indicator use a number of different colors of LEDs to indicate charge level of the earbuds such as red, yellow, and green. The indicator may use a number of LEDs to indicate charge level, e.g., one to four or one to five LEDs being illuminated. The indicator may use multiple LEDs but light a single LED with the position of the lite LED indicating the charge level. The notification may be transmitted to a computer. For example, the notification could be transmitted to an associated laptop and/or phone. In an example, an app on the associate computer provides a visual and/or audio indicator of the notification.

The predetermined charge level may be a charge level considered fully charged. The predetermined charge level may be a fraction of the fully charged condition. The predetermined charge level may correspond to an expected session time for the earbuds, for example, an hour, two hours, four hours, etc.

It will be appreciated that, within the principles described by this specification, a vast number of variations exist. It should also be appreciated that the examples described are only examples, and are not intended to limit the scope, applicability, or construction of the claims in any way.

What is claimed is:

1. A mouse for use with a computer system, the mouse comprising:
a body, the body containing a chamber, the chamber to hold an earbud;
a receiver to receive power from a source external to the mouse; and
a controller, to allocate power received from the external source between charging a battery in the mouse and charging a battery in the earbud.

2. The mouse of claim 1, wherein the chamber is sized to hold a pair of earbuds and the controller allocates power received from the external source between charging the battery in the mouse and charging batteries in the earbuds.

3. The mouse of claim 1, further comprising a sensor to measure a charge level of the battery in the mouse.

4. The mouse of claim 1, further comprising a sensor to measure a charge level of the battery in the earbud.

5. The mouse of claim 1, wherein the controller receives a measured charge level of the battery in the mouse and a measured charge level of the battery in the earbud and wherein the controller uses the measured charge levels of the batteries to determine the allocation of power received from the external source.

6. The mouse of claim 1, wherein receiver is a universal serial bus (USB) compatible connection.

7. The mouse of claim 1, wherein the receiver is a wireless power receiver.

8. The mouse of claim 1, further comprising a magnet to retain the earbud in the chamber.

9. A mouse for use with a computer system, the mouse comprising:
a body, the body containing a chamber, the chamber to hold a pair of earbuds;
a receiver to receive power from a source external to the mouse; and
a controller to allocate power received from the external source between charging a battery in the mouse and charging a battery in the earbud based on detected levels of charge in the battery in the mouse and the battery in the earbud.

10. The mouse of claim 9, wherein the chamber is accessible through a panel on a bottom of the mouse.

11. The mouse of claim 9, wherein the receiver comprises an antenna to receive wireless transmission of power from the source external to the mouse.

12. The mouse of claim 9, further comprising a magnet to align and retain the earbuds in chamber.

13. A method of charging earbuds, the method comprising:
determining, with a controller, if the mouse is coupled to an external power source;
if the mouse is coupled to an external power source, the controller distributing power from the external power source between a pair of earbuds in the mouse and the mouse; and
if the mouse is not coupled to an external power source, charging by the controller, the earbuds in the mouse from a battery in the mouse.

14. The method of claim 13, wherein the charging the earbuds is accomplished wirelessly.

15. The method of claim 15, further comprising providing a notification when the earbuds reach a predetermined charge level.
